(19) United States
(12) Patent Application Publication
(10) Pub. No.: US 2012/0321910 A1
(43) Pub. Date: Dec. 20, 2012

(54) METHODS AND APPARATUS FOR ATOMIC LAYER DEPOSITION ON LARGE AREA SUBSTRATES

(75) Inventor: Ofer Sneh, Boulder, CO (US)

(73) Assignee: SUNDEW TECHNOLOGIES LLC, Broomfield, CO (US)

(21) Appl. No.: 13/521,101

(22) PCT Filed: Jan. 11, 2011
(86) PCT No.: PCT/US11/20795

§ 371 Date: Jul. 9, 2012

Related U.S. Application Data
(60) Provisional application No. 61/294,323, filed on Jan. 12, 2010.

(51) Int. Cl. C23C 16/455; B32B 9/04

(52) U.S. Cl. 428/698; 118/719; 427/255.23; 428/701

(57) ABSTRACT

A method for depositing one or more materials on a substrate comprises placing at least a portion of the substrate proximate to a plurality of deposition modules such that the substrate and each of the plurality of deposition modules define a respective one of a plurality of process spaces therebetween. Each of the plurality of process spaces is in fluidic communication with one or more of a plurality of draw gas injection chambers. Subsequently, a first precursor gas and a second precursor gas are separately injected into the plurality of process spaces while injecting a draw gas into the plurality of draw gas injection chambers, and a sweep gas is injected into the plurality of process spaces while injecting substantially no draw gas into the plurality of draw gas injection chambers.

### FIELD OF THE INVENTION

The present invention relates generally to methods and apparatus for depositing materials on substrates, and, more particularly, to methods and apparatus for depositing materials on large area substrates using atomic layer deposition.

### BACKGROUND OF THE INVENTION

Atomic layer deposition (ALD) provides highly conformal material coatings with exceptional quality, atomic layer control, and uniformity. Coatings deposited by ALD are, for example, well suited for protecting many products from corrosion and harsh ambient conditions. Effective corrosion protective ALD coatings may only be about 200 to about 1,000 nanometers (nm) thick, making them thin enough not to impact the dimensions or the bulk properties of most of the parts and products on which they are deposited. Moreover, ALD coatings typically display excellent conformality and hermetic sealing properties. As a result, potential applications for ALD coatings are wide ranging. They include microelectronic packaging, medical devices, microelectromechanical systems, carbon nanotube assemblies, high-end consumer and aerospace parts, printed circuit boards, hard coatings over machining tools and plastic molding tooling, solar panels, organic light emitting diode based lighting and display panels, smart window coatings, food packaging, and a myriad of other applications.

Fundamentally, repetitive ALD process cycles consist at the very minimum of two reaction sub-steps. Typically, in a first reaction sub-step, a substrate is exposed to a first precursor gas MI, having a metal or metalloid element M (e.g., M=Al, W, Ta, Cu or Si) that is bonded to an atomic or molecular ligand L. The substrate surface is typically prepared to include hydrogen-containing ligands AH (e.g., A=O, N, or S). These hydrogen-containing ligands react with the first precursor gas to deposit a layer of metal by the reaction:

substrate-AH+MLₓ→substrate-AMLₓ₋₁+HL (1)

where the hydrogen containing molecule HL is a reaction by-product. During the reaction, the AH surface ligands are consumed, and the surface becomes covered with L ligands from the first precursor gas, which cannot react further with that gas. As a result, the reaction self-terminates when substantially all the AH ligands on the surface are replaced with AMLₓ₋₁ species. This reaction sub-step is typically followed by an inert-gas (e.g., N₂ or Ar) sweep sub-step that acts to sweep substantially all of the remaining first precursor gas from the process space in preparation for the introduction of a second precursor gas.

The second precursor gas is used to restore the surface reactivity of the substrate towards the first precursor gas. This is done, for example, by removing the L ligands on the substrate and re-depositing AH ligands. In this case, the second precursor gas typically consists of AH_{y} (e.g., AH_{y}═H₂O, NH₃, or H₂S). The reaction:

substrate-ML+AH_{y}→substrate-M-AH+HL (2)

converts the surface of the substrate back to being AH-covered (note that this reaction as stated is not balanced for simplicity). The desired additional element A is incorporated into the film and the undesired ligands L are substantially eliminated as volatile by-product. Once again, the reaction consumes the reactive sites (this time, the L-terminated sites) and self-terminates when those sites are entirely depleted. The remaining second precursor gas is then removed from the process space by another sweep sub-step.

The sub-steps consisting of reacting the substrate with the first precursor gas until saturation and then restoring the substrate to a reactive condition with the second precursor gas form the key elements in an ALD process cycle. These sub-steps imply that films can be layered down in equal, metered cycles that are all identical in chemical kinetics, deposition per cycle, composition, and thickness. Moreover, self-saturating surface reactions make ALD insensitive to precursor transport non-uniformities (i.e., spatial non-uniformity in the rate that the precursor gases impinge on the substrate) that often plague other deposition techniques like chemical vapor deposition (CVD) and physical vapor deposition (PVD). Transport non-uniformities may result from equipment deficiencies or may be driven by substrate topography. Nonetheless, in the case of self-saturating ALD reactions, if each of the reaction sub-steps is allowed to self-saturate across the entire substrate surface, transport non-uniformities become irrelevant to film growth rate.

As described generally above, an ALD process cycle requires two reaction sub-steps and their associated sweep sub-steps. If each reaction sub-step is further particularized into an injection sub-step, wherein the respective precursor gas is injected into the reaction space, and a reaction sub-step, then a single process cycle actually consists of six sub-steps in total:

1. MLₓ injection

2. MLₓ reaction

3. MLₓ sweep

4. AH_{y} injection

5. AH_{y} reaction

6. AH_{y} sweep.

The highest productivity is achieved when each of these sub-steps completes as quickly as possible. In fact, because a process frequently requires about 2,000 ALD process cycles to complete an encapsulation process, each cycle will preferably require less than about one second. Productivity is, of course, also affected by other factors. In addition to cycle time, productivity is also affected by equipment uptime (i.e., the fraction of the time that the equipment is up and running properly), cost of consumables (e.g., precursor gases, sweep gases), cost of maintenance, power, overhead (e.g., floor space), and labor.

Reaction rates during the reaction sub-steps tend to scale with the flux of precursor gases on the substrate, which, in turn, scales with the partial pressure of that precursor gas in the process space. Most ALD processes are performed at the low to moderate substrate temperature range of about 100-300 degrees Celsius (° C.). At these lower temperatures, reaction rates are relatively slow or only moderate in speed. As a result, substantial exposures (e.g., about 10²-10⁵ Langmuirs (L)) of precursor gas may be needed to reach saturation. In these cases, high precursor gas pressure is typically the only way to speed up the reaction sub-steps. Accordingly, reaction sub-steps are preferably executed at the highest possible pressure of undiluted precursor gas. In contrast, typically very minimal gas flow is needed during the reaction sub-steps to supplement for reactive precursor depletion. Moreover, higher gas flow rates will only result in extensive precursor waste. Since many of the precursor gases used in ALD are extremely reactive, un-reacted precursor gas that is swept through the process space swiftly drives the equipment to malfunction or to failure. It is therefore preferably that reaction sub-steps are performed with the highest pressures and the lowest gas flow rates.

Effective sweep sub-steps, in contrast, preferably utilize high gas flow rates of the sweep gas to substantially remove any precursor gas from the process space before introducing the complementary precursor gas into this space. Dilution by a factor of about 100-500 during a sweep sub-step is generally considered by those who are skilled in the art to be sufficient to promote high quality ALD growth. Required sweep sub-step times scale with the sweep residence time, τₛ=V×Pₛ/Qₛ, where V is the volume of the process space, Pₛ, is the pressure of sweep gas in the process space, and Qₓ is the gas flow rate of the sweep gas in the process space. Based on the 100-500 dilution criteria, effective sweep times will exceed about 4.5 τₛ. Based on this formula, one will recognize that, to reduce required sweep sub-step time, process space volume is preferably minimized when designing the deposition system. Moreover, sweep sub-step time may be reduced by using lower sweep gas pressures and higher sweep gas flow rates. The sweep sub-steps therefore display trends with respect to pressure and gas flow rate that are opposite to those described above for the reaction sub-steps.

Injection sub-steps drive a concurrent flow-out (“draw”) of sweep gas from the process space while it is loaded with the appropriate precursor gas. The time required for the injection sub-steps scales with injection residence time τᵢ=V×Pᵢ/Qᵢ, where Pᵢ is the pressure of the precursor gas in the process space, and Qᵢ is the gas flow rate of the precursor gas in the process space. Accordingly low pressures and high gas flow rates allow the injection sub-steps to be faster. Bearing in mind, however, that precursor waste and related equipment failure, downtime, and maintenance are perhaps the most dominant cost factors, best ALD practices generally dictate that injection sub-steps are not be carried out beyond 35% volume exchange (e.g., about 1×τᵢ) under these gas flow rate conditions. Otherwise, high concentration loading will result in excessive precursor waste during the injection sub-step. For example, to reach greater than 99% concentration of precursor gas in the process space during an injection sub-step, the required injection time of about 4.5τᵢ will result in more than 58% precursor waste just for that injection sub-step. This restriction further emphasizes the need for high pressure during the reaction sub-steps to compensate for less than 100% concentrations of precursor gas in the process space.

Based on these trends, one can see that conventional ALD clearly suffers from a fundamental tradeoff: injection and sweep sub-steps are made faster with lower pressures and higher gas flow rates while reaction sub-steps are made faster and less wasteful of precursor gases with higher pressures and lower gas flow rates. To overcome this tradeoff, process pressure and gas flow rates are preferably modulated in a synchronized manner with the different ALD sub-steps. Nevertheless, driving higher gas flow rates in many apparatus known in the art results in higher pressures so that any advantageous effects for ALD applications are lost. For example, the residence time τ=V×P/Q does not modulate when both pressure, P, and gas flow rate, Q, are modulated in phase with each other by roughly the same factor. Moreover, pressure/gas-flow-rate modulation techniques known in the art tend to employ relatively slow mechanical devices that modulate conductance (e.g., throttle valves) or devices that modulate pumping speed (e.g., devices that change the speed at which a component of the pump moves or rotates). These devices are not practical for the sub-second execution of ALD. For efficient ALD, the time required to modulate pressure and gas flow rates should not ideally exceed 10% of the process cycle time. For example, 100 milliseconds (ms) out of a one second cycle time leaves only about 25 ms for each pressure/gas-flow-rate transition (there are four such transitions per process cycle). Moreover, a cycle time in the range of 50 ms confines the transition times to very few ms. Excluding other drawbacks, a transition time of about 25 ms is at least 100 times faster than the speed of most mechanical and pump speed modulation methodologies. It goes without say that transition times in the millisecond range are too fast for mechanical devices to even start to respond.

A novel ALD apparatus and method were taught by the inventor of the present invention in U.S. Pat. No. 6,911,092, entitled “ALD Apparatus and Method,” commonly assigned herewith and hereby incorporated by reference herein. Aspects of this invention are shown in the schematic diagram shown in FIG. 1. As indicated in the figure, a “Synchronously Modulated Flow Draw” (SMFD) ALD system 80 comprises a first precursor gas source 81, a sweep gas source 82, and a second precursor gas source 83. These sources are plumbed into a first precursor gas valve 85, a sweep gas valve 84, and a second precursor gas valve 86, respectively, which control the flow of these process gases into inlets of a process space 87. Further downstream, a process space flow restriction element (FRE) 88 is attached to an outlet of the process space and carries gas drawn out of the process space into a small-volume draw gas introduction chamber (DGIC) 89. A draw gas source 92 is connected to the DGIC through a draw gas valve 91 and a draw gas FRE 90. Any gases drawn out of the DGIC enter a DGIC FRE 93 and then an abatement space 94, which contains an abatement surface 97. The abatement space is connected to an abatement gas source 95 and an abatement gas valve 96. The system is pumped by a vacuum pump 98.

The SMFD ALD system 80 is adapted to run process cycles comprising the six sub-steps described above. During sweep sub-steps, the draw gas valve 91 is closed and no draw gas is allowed to enter the DGIC 89. This, in turn, allows sweep gases injected into the process space to achieve relatively low pressures and relatively high gas flow rates. In contrast, during injection and reaction sub-steps, the draw gas valve is opened and draw gas is injected into the DGIC, allowing precursor gases injected into the process space to rapidly achieve relatively high pressures while accommodating relatively low gas flow rates. More particularly, given the small volume of DGIC and the high flow of the draw gas, a substantial pressure gradient quickly develops over the DGIC FRE 93 when draw gas is injected into the DGIC. As a result, pressure in the DGIC quickly increases and the pressure gradient over the process space FRE 88, ΔP_{Draw}, quickly decreases. In this manner, the gas flow rate out of the process space is modulated by effectively modulating ΔP_{Draw}. If the DGIC has a small volume, very fast transition speeds may be obtained. For example, a DGIC having a volume of about 75 cubic centimeters (cm³) implemented within a commercially available SMFD ALD system designed to deposit materials on eight inch wafer-sized substrates is capable of less than 5 ms transition times.

For gas abatement purposes, an abatement gas from the abatement source 95 is introduced through the abatement gas valve 96 into the abatement space 94 during sweep sub-steps to drive an efficient reaction with any precursor gases that may have passed through the process space 87 without being reacted. The products of this abatement reaction deposit as a solid film on the abatement surface 97, thereby effectively scrubbing the leftover precursor gas waste from the exhaust effluent. Advantageously, the high gas flow rate through the DGIC 89 effectively separates the abatement space from the process space to allow flexible abatement gas selection without affecting the actual ALD process. Abatement accomplished in this manner has been shown to extend pump life significantly over that normally seen in conventional ALD systems.

Based on this brief description as well as the details provided in U.S. Pat. No. 6,911,092, it will be clear to one skilled in the art that SMFD ALD methods and apparatus provide several advantages with respect to productivity, efficiency, and cost over other ALD methods and apparatus known in the art. However, SMFD ALD may not address possible performance limitations that may be tied to gas distribution and gas dynamics issues that occur when dealing with large size substrates. The distribution of sweep and reactive gases over large area planar substrates such as panels and sheets may, for example, be disadvantageously slow. Likewise, process chamber height cannot be reduced below certain limitations in order to avoid substantially large pressure gradients inside the deposition chamber.

These insufficiencies can be better understood by simply calculating the dependence of residence time on process chamber dimensions and pressure. Heinze indicated that the gas flow rate (in Liter×Torr/sec) through a rectangular cross section is:

$$Q = ( 4 / 48 ) ( {a}^{3} b / η ) ( \overline{P} / L ) ψ Δ P = 490 \frac{{a}^{3} b \overline{P} Δ P}{L} \qquad ( 3 )$$

wherein a, b and L (cm) are the height, width and length, respectively, of the rectangular flow path; η is the viscosity in poise (reasonably assumed to be ˜170 micro-poise (μpoise) as a good approximation); ΔP is the pressure differential across the rectangular flow path (Torr); P̅ is the average pressure (Torr); and ψ relates to the aspect ratio b/a and is given by the calculations of Williams (reasonably assumed to be ˜1 for the range of a/b<0.1 of interest).

Substituting Equation (3) into the equation for residence time, in turn, yields:

$$τ = \frac{VP}{Q} = \frac{{abL}^{2} \overline{P}}{490 {a}^{3} b \overline{P} Δ P} = \frac{1}{490 Δ P} {( \frac{L}{a} )}^{2} \qquad ( 4 )$$

wherein τ is expressed in ms. Clearly ΔP across the flow path and (L/a)² strongly impact residence time. In contrast, both, the width of the distribution path, b, and the actual pressure, P̅, are cancelled out and are less significant. Accordingly, when a typical ALD process where ΔP≦1 Torr and a=2 mm is applied to a large substrate with a surface area of, say, 1×1 m² (L=1 m), that ALD process will be hampered by long residence times (τ≧0.5 seconds (s)) as a result of (L/a)²˜2.5×10⁵. As a result, cycle times (even neglecting reaction times) are ≧5.5 s because an effective sweep sub-step requires 4.5×τ≧2.25 s and an effective injection sub-step requires 1×τᵢ≧0.5 s (for 35% exchange). Under these conditions, the deposition time to grow, for example, 100 nm of Al₂O₃, may even exceed 1 hour and 40 minutes, making the process several orders of magnitude too slow for cost effective throughput.

There is, therefore, a need for an improved ALD methods and apparatus that can coat large area substrates in a cost effective manner. There is also a need for ALD methods and apparatus that can cost-effectively coat continuously fed panels comprising wide flexible sheets.

### SUMMARY OF THE INVENTION

Embodiments of the present invention address the above-identified needs by providing methods and apparatus for effectively depositing materials on large area substrates.

In accordance with an aspect of the invention, a method for depositing one or more materials on a substrate comprises placing at least a portion of the substrate proximate to a plurality of deposition modules such that the substrate and each of the plurality of deposition modules define a respective one of a plurality of process spaces therebetween. Each of the plurality of process spaces is in fluidic communication with one or more of a plurality of DGICs. Subsequently, a first precursor gas and a second precursor gas are separately injected into the plurality of process spaces while injecting a draw gas into the plurality of DGICs, and a sweep gas is injected into the plurality of process spaces while injecting substantially no draw gas into the plurality of DGICs.

In accordance with another aspect of the invention, a product of manufacture is produced by the above-described method.

In accordance with even another aspect of the invention, an apparatus for depositing one or more materials on a substrate comprises a plurality of deposition modules, a plurality of DGICs, a substrate positioner, and a plurality of gas manifolds. The substrate positioner is operative to place at least a portion of the substrate proximate to the plurality of deposition modules such that the substrate and each of the plurality of deposition modules define a respective one of a plurality of process spaces therebetween. Each of the plurality of process spaces is in fluidic communication with one or more of the plurality of DGICs. The plurality of gas manifolds is adapted to separately inject a first precursor gas and a second precursor gas into the plurality of process spaces while injecting a draw gas into the plurality of DGICs, and to inject a sweep gas into the plurality of process spaces while injecting substantially no draw gas into the plurality of DGICs.

In accordance with one of the above-described embodiments, an ALD apparatus comprises an array of smaller size ALD modules. An optimized gas distribution design, together with appropriately shaped ALD modules and small gaps between the modules and the substrate, allow gases entering the process spaces to have very short residence times (i.e., <2 ms). More particularly, each of the ALD modules comprises an elongate plate that includes a distribution channel facilitating the fast transport of gases injected near the center of the plate along the longitudinal dimension of the plate. Once so transported, the gases need only cross less than half of the lateral dimension of the plate in order to fully occupy the entire process space. Furthermore, each ALD module is in fluidic communication with one or more DGICs, allowing the gas flow rates and pressures within the process spaces to be modulated in accordance with SMFD ALD methodologies. That is, precursor injection and sweep sub-steps are allowed to run at relatively low pressures and relatively high gas flow rates, while reaction sub-steps are allowed to run at relatively high pressures and relatively low gas flow rates. Depending on the characteristics of the substrate (e.g., dimensions, flexibility, and number of sides to be coated), the substrate may be stationary during deposition or may be continuously translated past the ALD modules during deposition, thereby allowing continuous reel-to-reel applications where appropriate. In addition, by configuring the ALD modules in zones producing different materials, more than one material may be coated on a single pass through the apparatus.

### BRIEF DESCRIPTION OF THE DRAWINGS

These and other features, aspects, and advantages of the present invention will become better understood with regard to the following description, appended claims, and accompanying drawings where:

FIG. 1 shows a schematic diagram of an ALD system in accordance with the prior art;

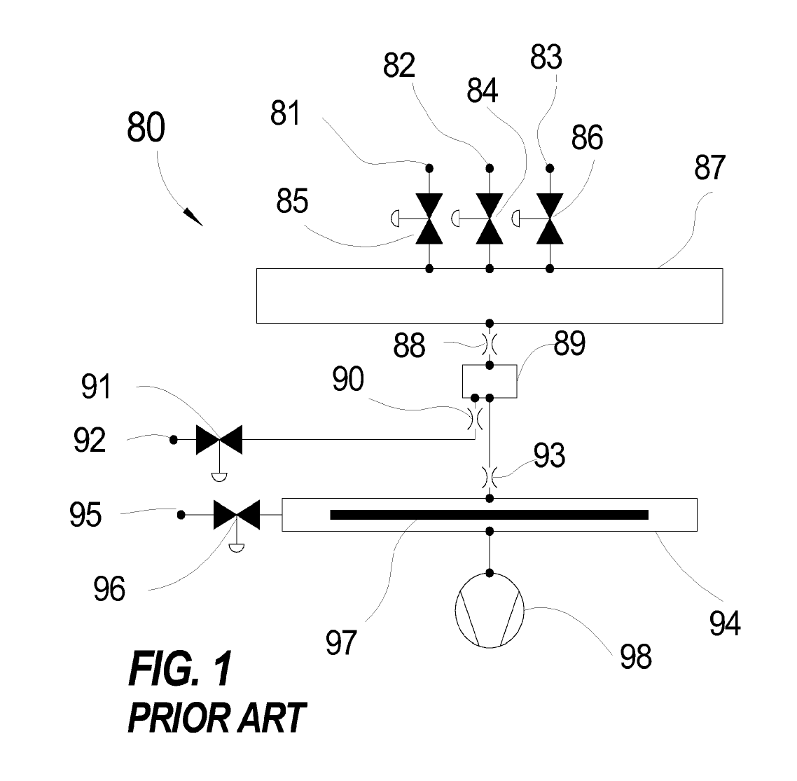

FIG. 2 shows a schematic diagram of a modular array ALD apparatus in accordance with an illustrative embodiment of the invention;

FIG. 3 shows a perspective view of an ALD module within the FIG. 2 ALD apparatus;

FIG. 4 shows a chart of residence time versus L/a.

FIG. 5 shows a schematic of the FIG. 3 ALD module;

FIG. 6 shows another perspective view of the FIG. 3 ALD module with an overlaid schematic;

FIG. 7 shows a sectional view of three FIG. 3 ALD modules in the FIG. 2 ALD apparatus;

FIG. 8 shows another sectional view of the FIG. 3 ALD modules in the FIG. 2 ALD apparatus;

FIG. 9 shows a sectional view of a modular array ALD apparatus in accordance with an illustrative embodiment of the invention for coating large rigid panels;

FIG. 10 shows a sectional view of a modular array ALD apparatus in accordance with an illustrative embodiment of the invention for coating continuously-fed, large rigid panels;

FIG. 11 shows a sectional view of a modular array ALD apparatus in accordance with an illustrative embodiment of the invention for coating reel-to-reel flexible substrates; and

FIG. 12 shows a sectional view of a modular array ALD apparatus in accordance with an illustrative embodiment of the invention for simultaneously coating two reel-to-reel flexible substrates.

### DETAILED DESCRIPTION OF THE INVENTION

The present invention will be described with reference to illustrative embodiments. For this reason, numerous modifications can be made to these embodiments and the results will still come within the scope of the invention. No limitations with respect to the specific embodiments described herein are intended or should be inferred.

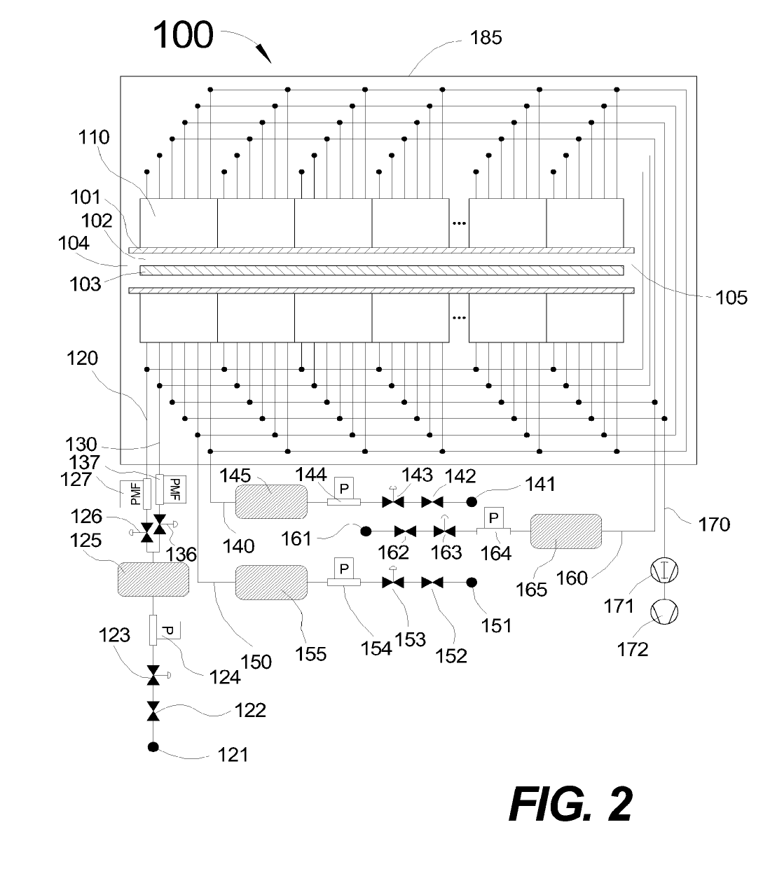

FIG. 2 shows a schematic view of a modular array ALD apparatus 100 in accordance with an illustrative embodiment of the invention for performing ALD. The apparatus comprises a narrow chamber (comprised of elongate plates 101 described below), wherein a substrate 103 is sandwiched between two arrays of ALD modules 110. The substrate is separated from the ALD modules by a small gap that defines the process space 102. The apparatus comprises an inlet interface 104 and an outlet interface 105. Each ALD module is plumbed so it can be individually supplied with five pressure-controlled process gases: a sweep gas 120, a draw gas 130, a first ALD precursor gas 140, a second ALD precursor gas 150, and an abatement gas 160. Evacuation of the ALD modules is via evacuation manifold 170. The apparatus is contained within a heated enclosure 185 that controls and maintains a process temperature.

For efficiency, the sweep and draw gases 120, 130 may be identical (e.g., N₂) and, therefore, may be provided by a single source. In this case, access to a single sweep and draw gas source 121 is provided through a manual shutoff valve 122, a pneumatic shutoff valve 123, and a pressure controller 124, which controls the pressure inside a pre-heating sweep and draw gas tank 125. Preferably the pressure in the tank is controlled to be several atmospheres in order to accommodate the supply of a large flow of pre-heated sweep and draw gas. The sweep gas temperature is preferably controlled to be similar to the process temperature or to an elevated temperature setting that is advantageous to the specific ALD process. Downstream from the preheating sweep and draw gas tank, the sweep gas is delivered through a pneumatic shutoff valve 126 to a pressure controller 127 that controls the sweep gas pressure to a pre-set pressure that is advantageous to the specific ALD process. Typically, this pressure will be in the range of about 50-500 Torr in order to set the sweep gas flow in the range from 70-500 standard liters per minute (sLm). Likewise, downstream from the pre-heating sweep and draw gas tank, the same gas (now the draw gas) is delivered through another pneumatic shutoff valve 136 to a pressure controller 137 that controls the draw gas pressure to a pre-set pressure that is also advantageous to the specific ALD process. Typically, this pressure controller controls the draw gas pressure in the range of 100-1000 Torr to set the draw gas flow in the range from 100-1200 sLm.

Manifolds for the delivery and distribution of precursors are also illustrated schematically in FIG. 2. The first ALD precursor gas 140, for example, is obtained from a first precursor gas source 141 equipped with a safety shutoff manual valve 142. The first precursor gas is further delivered through a pneumatic line valve 143 to a pressure controller 144. At this point, it is fed into a pressure controller 144, where its pressure is precisely controlled within a first precursor booster tank 145. Likewise, the second ALD precursor gas 150 is supplied/regulated using a similar arrangement by delivering the second precursor from a second precursor gas source 151 to a second precursor booster tank 155 using a safety shutoff manual valve 152, a pneumatic line valve 153, and a pressure controller 154.

Abatement gas 160 from abatement gas source 161 is controlled and distributed to all ALD modules 110 by a safety shutoff manual valve 162, a pneumatic line valve 163, a pressure controller 164, and an abatement gas booster tank 165. The exhaust of all modules 110 is collected and evacuated by evacuation manifold 170 to the vacuum pumps. In this particular embodiment, the pumps are a Roots blower 171 backed by a mechanical pump 172.

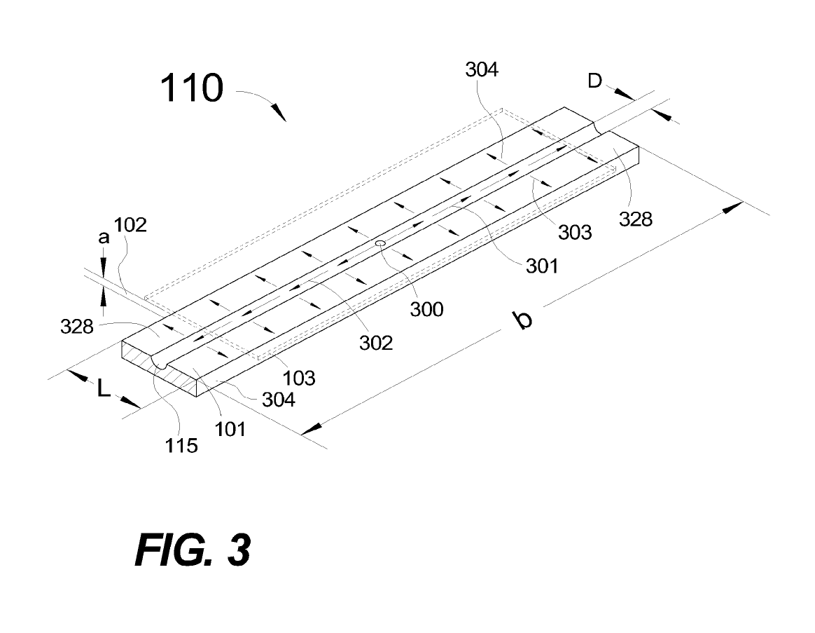

As indicated above, the apparatus 100 arranges an array of smaller size ALD modules 110 into a larger modular array to accomplish the deposition on the substrate 103. Aspects of the individual ALD modules and their incorporation into the larger apparatus are now described with reference to FIGS. 3-7

FIG. 3 illustrates a perspective view of an embodiment of a discrete ALD module 110 within the modular array ALD apparatus 100 and its relation to the substrate 103. The ALD module comprises an elongate plate (or flange) 101 of dimensions b and L (as defined by the figure) that is separated from the substrate by a small a gap 102 of dimension a, which forms the process space. A distribution channel 115, characterized by diameter D, runs parallel to the longitudinal axis of the elongate plate, substantially in its middle. Process gases (i.e., precursor and sweep gases) enter the process space through a conduit located substantially at the center 300 of the elongate plate. Once so introduced, the gases travels in the longitudinal direction b, as indicated by gas flow vectors 301 and 302, and in the lateral direction L, as indicated by gas flow vectors 303 and 304.

Advantageously, each individual ALD module 110 is characterized by short gas residence times. As described above in Equation (4), gas residence time, τ, is proportional to (L/a)²ΔP⁻¹. For this reason, gas introduced into the ALD module is rapidly distributed in the longitudinal direction because a relatively large (L/a)² is offset by a large pressure gradient ΔP. Likewise, the gas is rapidly distributed in the lateral direction because of the relatively small distance to travel. In this case, that distance is smaller than half of L.

For example, let it be assumed that a discrete ALD module like the module 110 has dimensions: b=50 cm, L=10 cm, D=1 cm, and a=2 mm. The residence time of the gas traveling in the lateral direction is given by Equation (4), while the residence time of the gas traveling in the longitudinal direction is given by substituting the Poiseulle equation for Equation (4):

$$τ = \frac{7.65 π η}{Δ P} {( \frac{L}{D} )}^{2} = \frac{4 \times {10}^{- 3}}{Δ P} {( \frac{L}{D} )}^{2} \qquad ( 5 )$$

wherein η=170 μPoise. Where, for example, the inlet pressure at the center conduit 300 is 4.5 Torr and the exhaust pressure is ˜1 Torr, ΔP across the distribution channel will be about 2.5 Torr and ΔP across the lateral flow path will vary between about 3.5 Torr (center) to 1 Torr (edge). Placing these values into Equation (4) indicates that the residence time in the lateral direction, τ₁, is τ₁<1 ms (τ is distributed between ˜1 ms at the edges down to 0.3 ms at the center). Likewise, placing these values into Equation (5) suggests that the residence time in the longitudinal direction (in the distribution channel 115), τ_{c}, is τ_{c}˜1 ms. Accordingly, the combined residence time for distribution of gas into the ALD module is τ<2 ms. Therefore, the preferred embodiment method may be implemented with very short precursor injection sub-steps (e.g., 2 ms for 35% replacement). Moreover, time efficient sweep sub-steps may also executed therein (e.g., ˜4.5τ≦9 ms for ˜99% replacement).

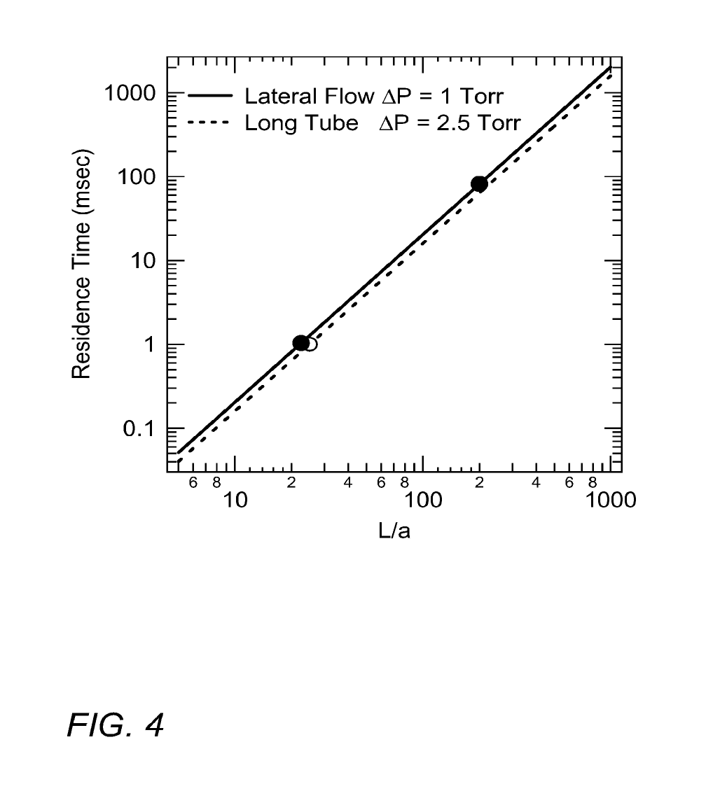

FIG. 4 displays the residence time as a function or (L/a) for a lateral flow with ΔP=1 Torr and for tubing with ΔP=2.5 Torr. Also displayed are the data points that correspond to the prior art and the current invention.

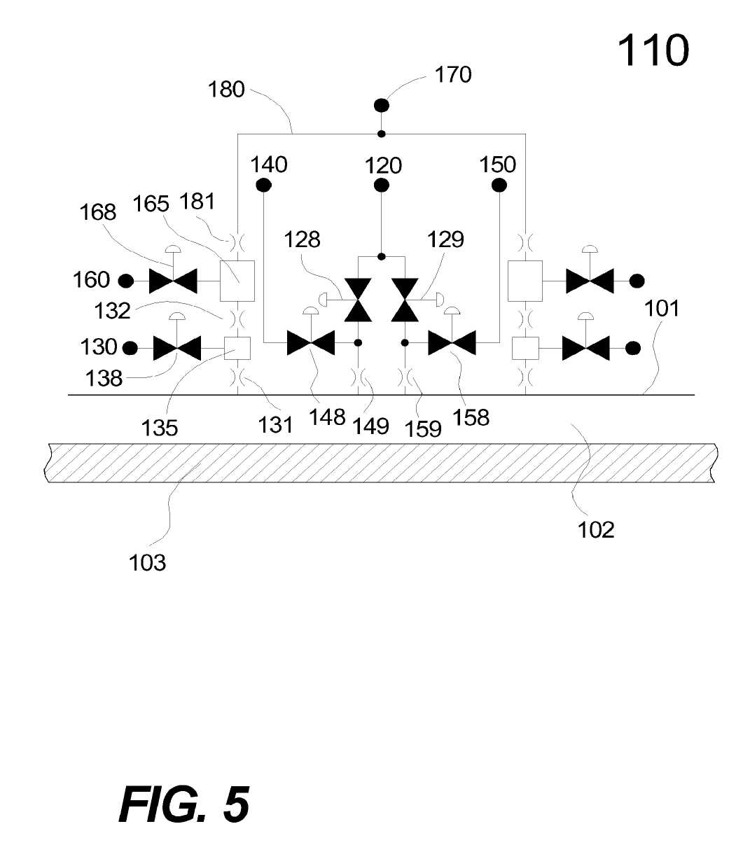

FIGS. 5-8 show additional aspects of the ALD module 110 as well as its associated gas processing elements. More particularly, FIG. 5 further illustrates the ALD module 110 with details of its gas control manifold. Pressure controlled sweep gas 120 is split into two feeds and fed through ultrafast ALD sweep gas valves 128 and 129 and through baffles 149 and 159 into the process space. The baffles are located near the center of the module 300. First and second ALD precursor gases 140, 150, in turn, are introduced through ultrafast three-way ALD precursor gas valves 148 and 158, respectively, feeding into the ALD manifold upstream to the baffles, and downstream from the sweep gas valves. The introduction of incompatible ALD precursors into two separated inlets, and the use of the baffles act to further separate the injection valve stack from the process space. Three-way ALD precursor gas valves are preferably of the “F-notated” flow design that allows complete and adequate sweep of precursor out of a three-way valve when the three-way valve is shut-off and a two-way sweep valve upstream is opened. F-notated three-way valve flow designs are common notations used in the industry and known to those who are skilled in the art. Preferably, the ultrafast ALD sweep gas valves are stacked without fittings, wherein valve 128 is attached with the flow direction pointing upstream. The designation of flow direction with respect to the construction of two-way valves is also known in the art. Advantageously, positioning the flow direction of valve 128 to point upstream prevents precursor gas from penetrating the diaphragm chamber space of valve 128. Similarly, valves 129 and valve 158 are positioned for optimized ALD, as well.

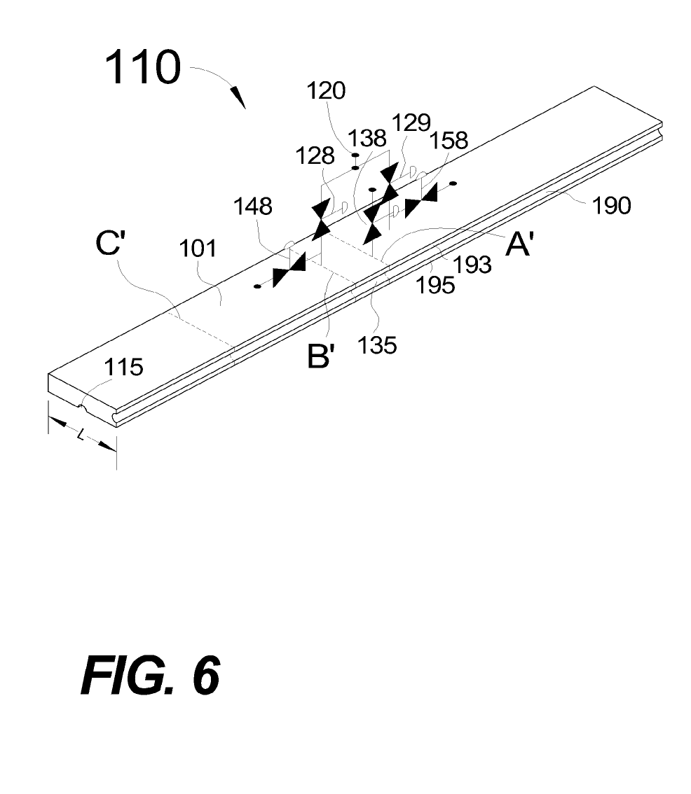

Even more details of the ALD module 110 are provided in the perspective view in FIG. 6. Here, the gas inlets through valves 128, 129, 148 and 158 are shown. Moreover, a concave side 190 is now visible on the module. The concave side comprises a lower curved edge 193 and an upper curved edge 195. The importance of this particular shape will become apparent below.

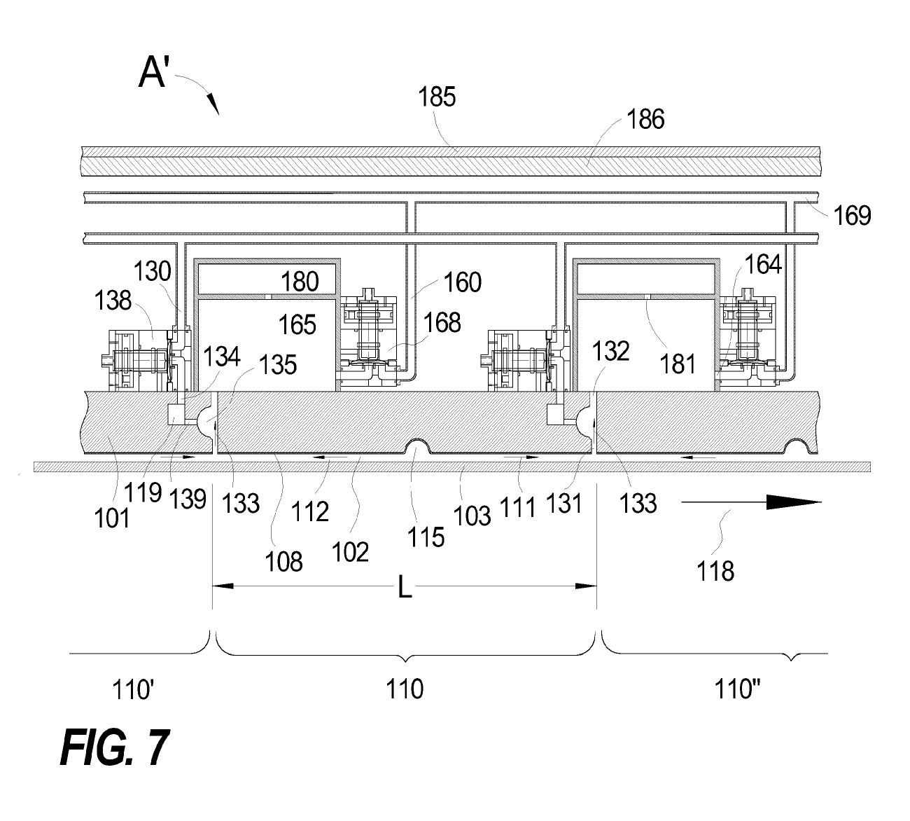

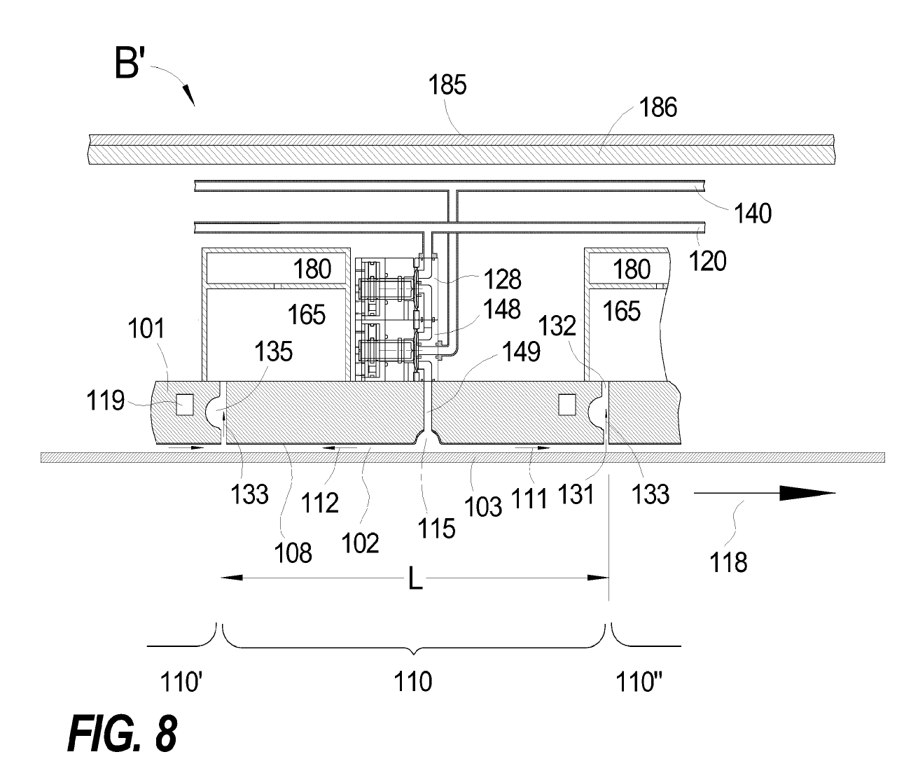

FIGS. 7 and 8 show cross-sectional side views of the ALD module 110 as it may be integrated into the modular array ALD apparatus 100 of FIG. 2. To better illustrate the integration of the module into the larger apparatus, both figures show the ALD module 110 (now called the “center module”) in place with two other adjacent modules, a left module 110′ and a right module 110″. FIG. 7 shows the modules cut along the A′ plane designated in FIG. 6, while FIG. 8 shows the modules cut along the B′ plane. So placed, the capability of the ALD modules to perform SMFD ALD becomes readily apparent.

Still referring to FIGS. 7 and 8, gases introduced into the center ALD module 110 through the baffles 149 and 159 traverse the module in the longitudinal direction (i.e., in the direction normal to the cross-sectional plane) largely through the distribution channel 115, while, at the same time, traversing laterally (i.e., in the direction parallel to the cross-sectional plane) across the ALD process space 102 between the elongate plate 101 and the substrate 103 (as illustrated schematically by arrows 111 and 112). Exhaust openings 131 are formed between the lower curved edge of the center module 110 and the flat edge of the right module 110″, as well as between the lower curved edge 195 of the left module 110′ and the flat edge of the center module. Gas flows through these exhaust openings as illustrated by arrows 133 into DGIC spaces 135, which are physically defined by the modules themselves. Further downstream, FRE openings 132 are formed between the upper curved edge 193 of the center module and the flat edge of the right module, and between the upper curved edge of the left module and the flat edge of the center module, leading the flow into abatement spaces 165. Even further downstream, FREs 181 lead the gas flow from the abatement spaces into the pumping conduits 180, wherein the exhaust is combined in manifold 170 and routed to the vacuum pumps 171, 172. To implement SMFD ALD, draw gas valves 138 are used to introduce draw gas into the DGICs 135 between modules. Moreover, a conduit 134 built into the ALD modules is utilized to introduce the draw gas into draw control distribution channels 119, wherein the draw gas is distributed across the longitudinal axis and then injected into the DGICs through nozzles 139.

Abatement space 165 is used to conduct highly reactive, low pressure processes to convert leftover ALD precursors into solid films. In particular, a mixture of CH₃(NH)NH₂ and O₃ has been proven to promote a very effective low temperature reaction with a wide range of ALD precursors. The preferred method introduces the abatement gas 169 from an abatement supply line 160 through fast abatement valve 168. Timing is optimized to coincide with the injection, reaction and the initial 2τ portion of the sweep sub-steps. The heated abatement space comprises a large area trap element (not shown) wherein the growth of solid films from scrubbed exhaust effluents is directed. Given the typically large abatement space, the synchronized pulsation of abatement gas by the fast abatement valves modulates the concentration of abatement gas within the abatement space.

U.S. Pat. No. 7,744,069 by the inventor of the present invention, entitled “Fail-safe pneumatically actuated valve with fast time response and adjustable conductance,” commonly assigned herewith and hereby incorporated by reference herein, teaches ultrafast, highly conductive, long cycle-lifetime valves that are suitable for sub-millisecond routing of gas at high rates such as the range of 28-66 Hertz (Hz) necessary for conducting an ALD process at 30-70 ms per cycle. When cycling at these short cycle times, the sweep gas valves 128, 129 and the draw gas valves 138 fire at about 28-66 Hz, while the precursor valves 148, 158 and the abatement valves 168 fire at about 14-33 Hz. While these valves are faster than 1 ms, an embodiment may implement fast-reacting ALD precursors (e.g., Al(CH₃)₃ (TMA)) with a relatively low pressure doses. Accordingly, the pressure at the center 300 of the ALD modules 110 is typically set to less than 4.5 Torr to essentially reduce the injection flow and the overall partial pressures in the process space 102. Alternatively, precursor dilution with carrier gas may be implemented to inject pre-diluted precursor.

As indicated in FIG. 2, larger substrates are accommodated by combining a plurality of ALD modules 110. For example, a stationary 1 meter (m)×1 m panel may be coated by an m×n=2×10 modular array (wherein m is the number of modules arranged in the longitudinal direction b of the individual modules; and n is the number of modules arranged in the lateral direction L of the individual modules) if each module is 50 cm×10 cm. Alternatively, a smaller modular array may be used, for example 2×5 modular array with the same size ALD modules, while the panel is translated parallel to the lateral L direction. In this case, the translation speed defines the final thickness.

Efficient and rapid precursor injection is executed by the combination of ultrafast injection and SMFD. Concurrent with the distribution of gas, the synchronized draw gas controlling flow raises the pressure at the DGICs 135 to about 2 Torr. In the next 1-3 ms, the excess pressure above ˜2 Torr, mainly in the center 300 of the ALD modules 110, is drawn out of the module. Accordingly, an estimated 25-30% of the gas is lost. Loaded at approximately 33% per injection of 1×τ the material, loss is estimated to be in the range of 9%. Nevertheless, this loss is well spent on achieving a quick distribution, up to the pressure of ˜2 Torr at 33% loading within 3-5 ms.

Based on these values, the partial pressure of precursor gas in the process space is about 660 mTorr, which is equivalent to ˜6.6×10⁵ Langmuir/s (1 Langmuir=10¹⁵/cm²). At that level many ALD reactions saturate to exceed 95% within 2-20 ms. The combination of injection, reaction and sweep time adds up to cycle times in the range of 30-70 ms. For example a 1 m×1 m panel may be coated by a 2×10 modular array with deposition rate of R˜100 nm/min for Al₂O₃ ALD. Alternatively, if a smaller modular array ALD apparatus is utilized (e.g., m×n=2×5), and the substrate panel is translated parallel to the lateral L direction, the translation speed defines the final thickness. For example, to achieve t=100 nm thick Al₂O₃, the panel would need to be translated at a speed of about v=10×n×R/t=50 cm/min. Likewise a 2×20 array apparatus (2 meters long) can continuously produce 10×20×100/100=2 meter/min deposition rates.

Continuing to consider ALD modules 110 wherein b=50 cm, L=10 cm, D=1 cm, and a=2 mm, the conductance of the distribution channel and the lateral flow paths are 50 L/s and 87 L/s, respectively. The conductance and ΔP of the lateral path determine the flow to be Q=CΔP ˜7 sLm. Accordingly the flow of a 2×10 array is 140 sLm. Since the injection steps are limited to 2 ms, this flow corresponds to a very small dose of chemical at <5 standard cubic centimeters (scc) or 1.25×10²⁰ molecules per cycle for the entire array. The array covers a 1×1 m² area wherein the cycle incorporates ˜5×10¹⁸ atoms of Al during the ALD of Al₂O₃. Accordingly, the utilization of TMA is only ˜4% under these, excessive dose conditions. However, given the reactivity of TMA, the reaction will saturate to more than 95% within less than 2 ms. Therefore, TMA injection is preferably shortened to tradeoff better material utilization and consequently longer time between maintenance with a somewhat longer reaction time. For example, a 10 ms extended saturation time (instead of 2 ms) may be traded for an increased chemical utilization up to 20%.

The time constant for DGIC pressure rise and fall in synch with the injection and reaction sub-steps is preferably chosen to be substantially similar, but slightly longer than the injection sub-steps. For example, 2-3 ms is a good match to the injection residence time of τ₁≦2 ms. The draw gas flow that achieves this response is determined by the conductance of the FRE 132. The conductance of the FRE 131 is chosen to produce a pressure gradient of 1 Torr during the injection and sweep sub steps (for example, as described above, per 7 sLm of flow). Accordingly the conductance of the FRE 131 is C₁₃₁=Q/ΔP=88.7 L/s. The geometrical factor of the FRE 131 is given by G₁₃₁=C₁₃₁/ P̅=57 L/Torr×sec, wherein P̅ is the average pressure across the FRE 131. The pressure inside abatement space 165 is defined by the flow and the conductance of the FRE 181 to be at 0.2 Torr. Accordingly the pressure gradient across the FRE 132 per injection flow of 7 sLm is ΔP=0.8 Torr. The conductance of the FRE 132 is C₁₃₂=Q/ΔP=111 L/sec and the geometrical factor is G₁₃₂=185 L/Torr'sec. Finally the conductance of the FRE 181 leading into pumping conduit with pressure at 50 mTorr is set at C₁₈₁˜600 L/sec, and the geometrical factor is G₁₈₁˜5,000 L/Torr×sec. Timed with the completion of injection sub-steps the pressure inside DGIC 135 is raised to 2 Ton to match the injection pressure at the ends 328 of module 110 (FIG. 3). Accordingly the draw flow, Qpe, is calculated from:

$$\begin{matrix}{Q}_{DC} = \frac{{G}_{132} ( 2 + {P}_{165} )}{2} ( 2 - {P}_{165} ) & ( 6 ) \\ {Q}_{DC} = \frac{{G}_{132} ( {P}_{165} + 0.05 )}{2} ( {P}_{165} - 0.05 ) & ( 7 )\end{matrix}$$

wherein P₁₆₅ is the pressure inside abatement space 165 when draw gas is flowing at Q_{DC}. Combining both equations, the unknown parameters arc calculated to be, P₁₆₅=0.38 Torr and Q_{DC}=28 sLm.

An estimate for the preferred embodiment average N₂ flow accounting to sweep and draw control with their approximate 50:50 share of the cycle time is 17.5 sLm per module. Likewise, the total N₂ flow of a m×n=2×10 apparatus with 1×1 m² total area is about 350 sLm. Given the high Q_{DC} draw control flow, draw gas distribution is easily done with the draw control distribution channels 119 that run parallel to the long axes of modules 110. For example, a draw control distribution channel with a round cross section of 0.75 cm, an average pressure of P₁₁₉˜20 Torr, and ΔP˜10 Torr, displays a residence time of ˜0.8 ms to pressurize the channel with a 10 Torr gradient. As indicated in FIG. 7, the draw control distribution channels are in fluidic communication with the DGICs 135 through a set of nozzles 139, which are appropriately made with different diameters to unify the flow into the draw control distribution channel, compensating for the 10 Torr gradient from center inlet 300 to edges 304 of the modules (FIG. 3). These nozzles define the draw control flow of 28 sLm per module. Per channel 119 diameter, pressure, and flow, the response time of the draw control distribution channel is τ=0.6 ms. Accordingly, channel typical pressurizing-de-pressurizing (3τ to reach 95%) is ˜1.8 ms which, together with 0.8 ms for channel distribution sums up to the right range of ˜2.6 ms.

In another aspect of the example, typical abatement space cross-section of 5×5 cm² corresponds to a volume of V=1.25 L per module. At 17.5 sLm average flow and 0.29 Torr average pressure, the residence time inside the abatement space 165 is τ˜1.6 s. This time constant is 20-50 times longer than the cycle time. As a result, another preferred abatement mode of introducing abatement gas simply comprises a steady state introduction of abatement gas through a set of mass flow controllers (MFCs).

Modular ALD apparatus in accordance with aspects of the invention may, for example, lay down 1-6 nm of ALD films per second on all exposed surfaces including substrate 103 and exposed surfaces of the apparatus 101. Film accumulation on the exposed surfaces exceeding 200 μm is not recommended. This maintenance interval may be equivalent to 9-43 hours. To facilitate fast maintenance turnaround, the exposed surfaces of the apparatus are preferably lined with quickly releasing liners 108 (FIGS. 7 and 8). In that case, chamber refreshing maintenance merely comprises quick replacement of coated liners with uncoated ones. The quickly releasing liners are preferably attached or taped to the remainder of the apparatus with residue free, high temperature, pressure sensitive silicone adhesives that were commercialized for the plasma spray, thermal spray, flame spray, and high velocity oxygen thermal (HVOF) industries. For example, the CHR pressure sensitive adhesive tapes product lines from Saint-Gobain (Courbevoie, France) may be appropriate since they are especially formulated for up to 260° C. in harsh process conditions, are easily removable, are residue-free when removed, and are able to accumulate up to 750 μm of film without peeling. In particular, glass cloth based tapes are highly conformal, easy to apply and remove, and are conducive to thick film accumulation.

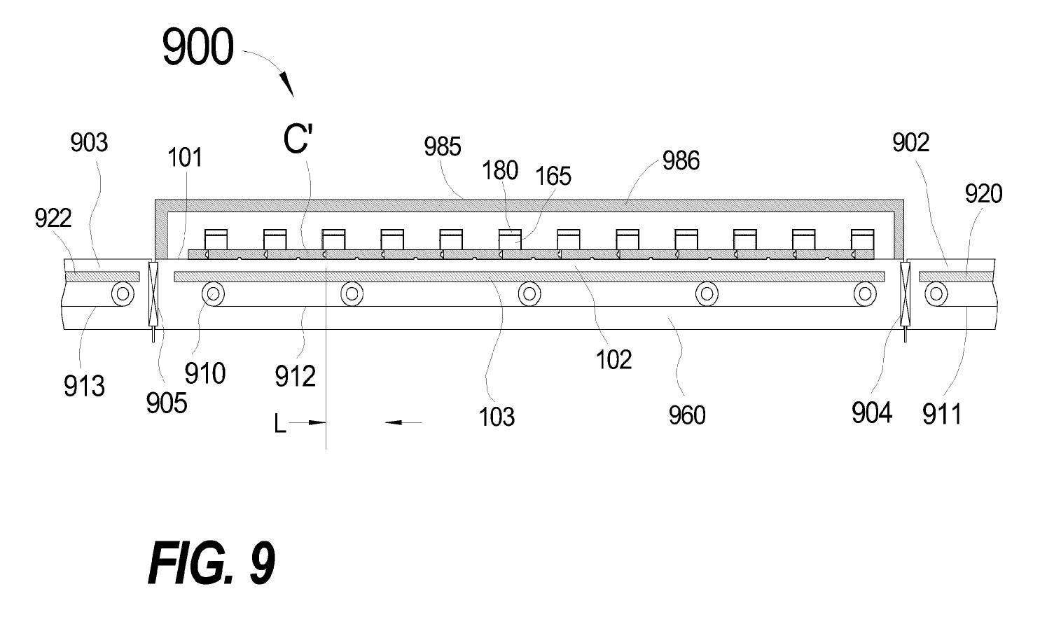

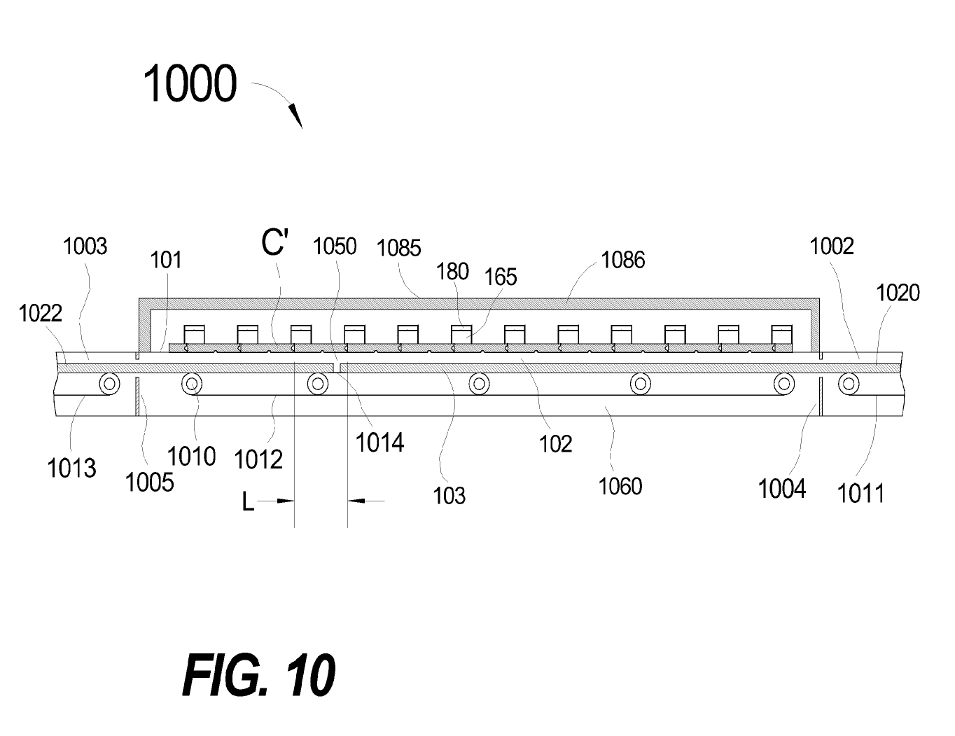

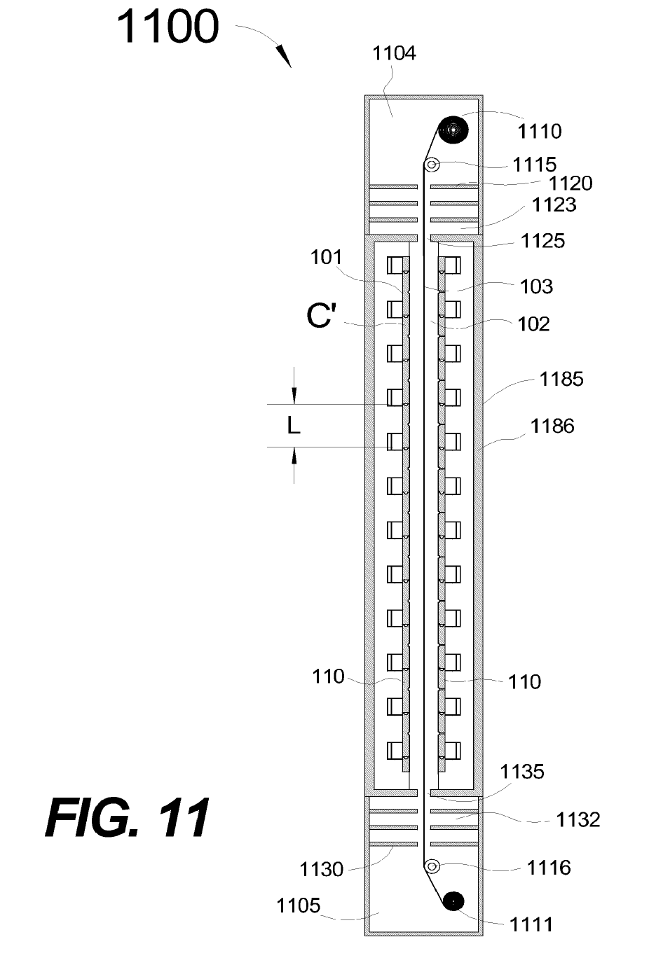

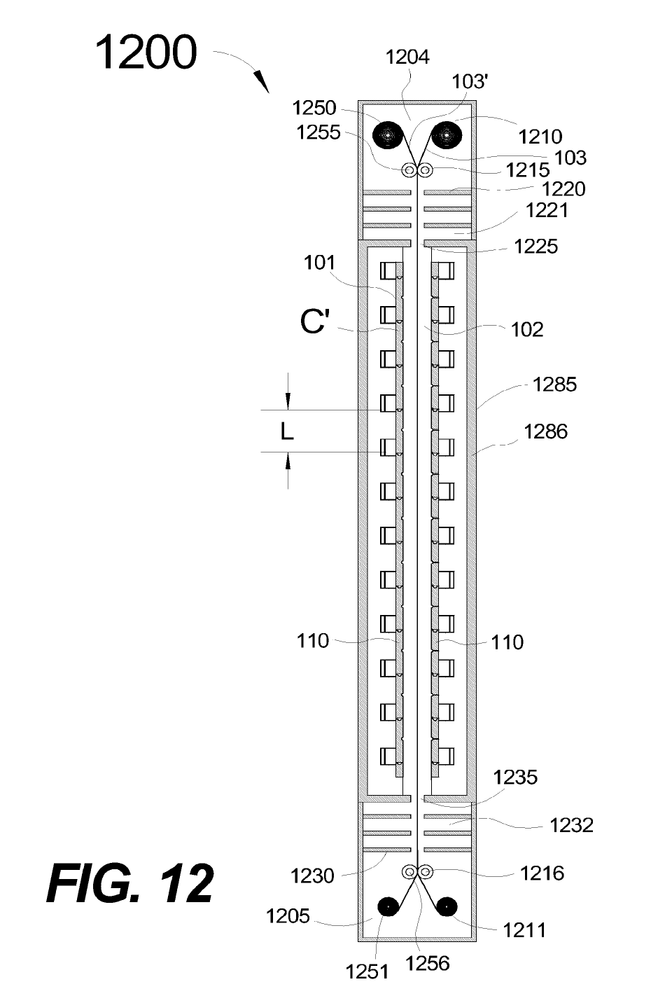

FIGS. 9 and 10 go onto to detail illustrative modular array ALD apparatus in accordance with illustrative embodiments of the invention for coating relatively large, rigid panels. FIGS. 11 and 12, moreover, show illustrative modular array ALD apparatus embodiments for coating continuous flexible sheets which are provided on reels and which are continuously fed through the apparatus from one end to the other.

More particularly, in FIG. 9, a cross-sectional view of a modular array ALD apparatus 900 comprising a modular array of ALD modules 110 is shown. For simplicity, the cross section through the modules occurs on the plane C′ shown in FIG. 6. A substrate panel 103 is conveyed into the chamber via conveyor rollers 910 and a processing conveyer 912. After utilizing an inlet slit valve 904 and an outlet slit valve 905 to isolate the chamber, the process is executed within the confined space 102. Complementary purge and evacuation of the back space 960 and local purge of the slit valves, the side edges of panels 103, and the rollers is preferred. Notably, the rollers are positioned outside the process space to reduce particles. Moreover, the rollers and conveyor belt widths are preferably not as wide as the substrate panels, and the substrate edge is close to the chamber walls to further avoid the remote possibility of ALD precursors reaching the rollers and/or the conveyor belt as well as the possibility that particles dislodged from the rollers and conveyor belt reach the process space. An inlet load-lock chamber 902 and an outlet load-lock 903 are equipped with inlet and outlet conveyors 911 and 913, respectively, to facilitate fast exchange of panels without process chamber venting. During typical operation, a coated substrate panel 922 is removed from the vented outlet load-lock chamber while the substrate panel 103 is coated and the outlet load-lock is then sealed and evacuated. Similarly, an uncoated substrate panel 920 is loaded into the vented inlet load-lock chamber while the panel substrate 103 is being coated. Subsequently, the inlet load-lock chamber is evacuated. Optionally, the inlet load-lock chamber can include one or more pre-coating process capabilities such as, but not limited to, ozone cleaning, outgassing, preheating, and surface activation. In addition, the outlet load-lock chamber may optionally be capable of performing post-coating processes such as annealing in various ambients. The modular array ALD apparatus is contained by an enclosure 985 and thermal insulation 986. Process temperature is preferably maintained by fast and efficient heat convection, as known in the art. Advantageously, the modular array ALD apparatus can be configured to deposit several different layers so as to create a film stack if so desired, as will be apparent to one skilled in the art.

In yet another embodiment, a modular array ALD chamber 1000 in FIG. 10 is configured as a continuous inline panel coater wherein substrate panels 103 are continuously conveyed into and out of a process space 102 from an inlet interface 1002 to an outlet interface 1003. Substrate panels start on an inlet conveyor 1011 that hands the panels off to a processing conveyer 1012 by passing the panels through a differentially pumped inlet partition 1004. Coated panels, in turn, emerge in the outlet interface where they are transferred to an outlet conveyor 1013 after passing through a differentially pumped outlet partition 1005. The back side of processing conveyor 1012 is evacuated and the panels translate continuously with minimized gaps 1050. To prevent gas loss through these gaps, as well as to prevent deposition on the processing conveyer (which is driven by rollers 1010), the ends of adjacent substrate panels are connected by strips of tape 1014. The tape is preferably attached at the back, uncoated side of the substrate panels. Many types of high temperature, residue-free, deposition compatible tapes are suitable for this application, such as the 21005-7R glass fabric tape manufactured by Saint-Gobain.

FIG. 11 illustrates a continuous reel-to-reel (R2R) modular array ALD apparatus 1100 for simultaneous two-sided coating of flexible substrate sheets. There are many applications for R2R processing, ranging from converting standard polymer sheets (e.g., polyethylene terephthalate (PET)) into highly protective moisture barriers to producing flexible solar panels over high area substrates. In this embodiment, the apparatus includes an inlet interface module 1104 and an outlet interface module 1105, which are separated from the process space 102 by a series of slotted inlet partitions 1120 and slotted outlet partitions 1130, respectively. A substrate sheet 103 originates from a source reel 1110, passing through an inlet tension roller 1115 that together with an outlet tension roller 1116, positions the sheet for the correct location across from arrays 110 in the ALD process space 102. The coated sheet is collected onto a collection reel 1111. Inlet spaces 1123 between the inlet partitions are utilized for differential pumping to allow a higher pressure at the inlet real than that in the process space, such as atmospheric pressure. Additional functions, such as pre-deposition processing, may also be executed within the inlet spaces. Similarly, outlet spaces 1132 defined by the slotted outlet partitions are used for differential pumping and/or post coating processing. Preferably, an entry slot 1125 and an exit slot 1135 are purged to improve separation between the process space and the interface modules. The apparatus is contained within an enclosure 1185 and thermal insulation 1186. Process temperature is maintained by convection heating, as known in the art. If desired, the apparatus may be positioned vertically as displayed in the figure.

Lastly, an R2R modular array ALD apparatus 1200 for a single side coating of a continuous flexible sheet is illustrated in FIG. 12. In this illustrative embodiment, two substrate sheets 103 and 103′ are fed into the process space 102 from source reels 1210 and 1250, and collected at collection reels 1211 and 1251. An inlet interface module 1204 comprises inlet slits 1220, inlet spaces 1221, and an inlet slot 1225, while an outlet interface module 1205 comprises outlet slits 1230, outlet spaces 1232, and an outlet slot 1235 in a manner similar to that used in FIG. 11. The substrate sheets are directed through the process space by inlet tension rollers 1215 and 1255 and outlet tension roller 1216, 1256, which act to hold the sheets back to back as they pass through the process space. Obviously, such a design has the advantage of being able to coat two sheets simultaneously so long as the sheets only require a single-sided coating.

Notably, several different zones may be created within the process space 103 of the continuously-fed modular array ALD apparatus 1000, 1100, 1200 so that several different layers may be deposited on the substrate panel or R2R sheet as it is fed through the process space. Creating these zones becomes simply an issue of providing the individual ALD modules with the correct reactants along the path of the substrate as well as making sure that the zones are sufficiently isolated from one another to avoid the mixing of different precursor gases. Notably, the different zones may also be run at different temperatures simply by adapting the heating source in a manner that will be readily apparent to one skilled in the art. As just one example, for solar cell applications, a first zone of the apparatus may be utilized to coat an area-enhanced etched aluminum foil substrate with a layer of 50 nm Mo ALD to facilitate a bottom contact. Subsequently, in a second zone, a thin conformal layer of 50-100 nm of Cu₂S, Si, CdTe or FeS₂ may be deposited. In a third zone, a thin conformal junction layer of doped TiO₂ (for the case of Cu₂S) is grown. Finally, in a fourth zone, 200-500 nm of ZnO-based transparent conducting oxide (TCO) layer completes the stack. Typically, these depositions may be conducted at a single temperature between about 100 and about 250° C.

Whenever actively translating the substrate in the above embodiments as well as any others falling within the scope of the present invention, precautions are preferably taken to minimize the generation of particles which may coat the substrate and produce defects. Accordingly, motion is ideally kept at the necessary minimum and the usage of pulleys and rollers in the deposition space is preferably avoided. Accordingly, as detailed above, pulleys and rollers are placed outside of the ALD space, instead being substantially contained in differentially pumped and/or purged spaces wherein contact with the process is prevented or greatly minimized and the probability of particles reaching the process space is very small. Additionally, the preferred apparatus and methods avoid bending the substrate in the process space which acts to reduce the possibility of substrate flaking or particle generation. Likewise, any type of friction or pseudo contact in the process space is avoided and the deposition space is maintained at low pressure (e.g., <10 Torr) to avoid the risk of particles being transported by turbulent gas dynamics. Finally, precursor mixing and residual CVD reactions are avoided because such reactions promote deposition on chamber components and thereby promote the formation of particles, which vastly shorten maintenance intervals.

It should be emphasized that the above-described embodiments of the invention are intended to be illustrative only. Other embodiments can use different types and arrangements of elements for implementing the described functionality. In so much as aspects of the present invention teach methods of manufacture, the invention is further intended to encompass products of manufacture that are formed at least in part using those methods. Moreover, all the features disclosed herein may be replaced by alternative features serving the same, equivalent, or similar purpose, unless expressly stated otherwise. Thus, unless expressly stated otherwise, each feature disclosed is one example only of a generic series of equivalent or similar features.

What is claimed is:

1. An apparatus for depositing one or more materials on a substrate, the apparatus comprising:
a plurality of deposition modules;
a plurality of draw gas injection chambers;
a substrate positioner, the substrate positioner operative to place at least a portion of the substrate proximate to the plurality of deposition modules such that the substrate and each of the plurality of deposition modules define a respective one of a plurality of process spaces therebetween, each of the plurality of process spaces in fluidic communication with one or more of the plurality of draw gas injection chambers; and
a plurality of gas manifolds, the plurality of gas manifolds adapted to separately inject a first precursor gas and a second precursor gas into the plurality of process spaces while injecting a draw gas into the plurality of draw gas injection chambers, and to inject a sweep gas into the plurality of process spaces while injecting substantially no draw gas into the plurality of draw gas injection chambers.

2. The apparatus of claim 1, wherein the apparatus deposits the one or more materials on the substrate by atomic layer deposition.

3. The apparatus of claim 1, wherein each of the plurality of deposition modules comprises a respective one of a plurality elongate plates.

4. The apparatus of claim 3, wherein each of the plurality of elongate plates defines one or more respective injection passages that penetrate through the elongate plate proximate to a center of the elongate plate.

5. The apparatus of claim 4, wherein at least a portion of the plurality of gas manifolds is operative to inject the first precursor gas, the second precursor gas, and the sweep gas through the injection passages in the plurality of elongate plates.

6. The apparatus of claim 3, wherein each of the plurality of elongate plates defines a respective channel that is substantially centered on a lateral axis of the elongate plate and runs substantially parallel to a longitudinal axis of the elongate plate.

7. The apparatus of claim 3, wherein each of the plurality of elongate plates defines a rectangle, each rectangle characterized by a substantially common lateral length and a substantially common longitudinal length.

8. The apparatus of claim 7, wherein the substantially common longitudinal length is between about four and about ten times greater than the substantially common lateral length.

9. The apparatus of claim 7, wherein the common longitudinal length is about five times greater than the substantially common lateral length.

10. The apparatus of claim 7, wherein the substantially common lateral length is less than 50 times the average distance between the substrate and each of the plurality of deposition modules.

11. The apparatus of claim 1, wherein each of the plurality of elongate plates comprises a respective side defining a concave depression.

12. The apparatus of claim 11, wherein each of the plurality of elongate plates comprises a respective draw gas passage that is in fluidic communication with the concave depression.

13. The apparatus of claim 12, wherein at least a portion of the plurality of gas manifolds is operative to inject the draw gas through the draw gas passages in the plurality of elongate plates.

14. The apparatus of claim 1, wherein the plurality of draw gas injection chambers is physically defined by the plurality of deposition modules.

15. The apparatus of claim 1, wherein each of the plurality of draw gas injection chambers is defined by a respective gap between two of the plurality of deposition modules.

16. The apparatus of claim 1, further comprising a plurality of abatement spaces, each of the plurality of abatement spaces in fluidic communication with one or more of the draw gas injection chambers and comprising a respective abatement surface on which the first and second precursor gases are operative to form a film in the presence of an abatement gas.

17. The apparatus of claim 16, wherein the abatement gas comprises CH₃(NH)NH₂.

18. The apparatus of claim 16, wherein the abatement gas comprises at least one of O₃, H₂O₂, and HCOOH.

19. The apparatus of claim 1, further comprising one or more vacuum pumps in fluidic communication with the plurality of abatement spaces.

20. The apparatus of claim 1, wherein the substrate is substantially rigid.

21. The apparatus of claim 1, wherein the substrate is substantially flexible.

22. The apparatus of claim 1, wherein the substrate emanates from a source reel.

23. The apparatus of claim 22, wherein the source reel is separated from the plurality of process spaces by a series of partitions defining gaps therebetween, the gaps being differentially pumped.

24. The apparatus of claim 1, wherein the substrate is collected by a collection reel.

25. The apparatus of claim 24, wherein the collection reel is separated from the plurality of process spaces by a series of partitions defining gaps therebetween, the gaps being differentially pumped.

26. The apparatus of claim 1, wherein the substrate positioner comprises a plurality of conveyer belts driven by a plurality of rollers.

27. The apparatus of claim 1, wherein the substrate positioner comprises a plurality of tensioning reels.

28. The apparatus of claim 1, wherein the apparatus further comprises a plurality of substrate heaters operative to heat the substrate while the one or more materials are deposited.

29. The apparatus of claim 1, wherein the plurality of substrate heaters are operative to heat the substrate primarily by convection.

30. The apparatus of claim 1, wherein the apparatus comprises a plurality of heating zones, each heating zone operative to heat the substrate to a different temperature.

31. The apparatus of claim 1, wherein the plurality of deposition modules are disposed on opposing sides of the substrate.

32. The apparatus of claim 1, wherein the apparatus is operative to simultaneously deposit the one or more materials on two opposing sides of the substrate.

33. The apparatus of claim 1, wherein the apparatus is operative to simultaneously deposit two different materials on two opposing sides of the substrate.

34. The apparatus of claim 1, wherein the apparatus is operative to simultaneously deposit the one or more materials on two different substrates.

35. The apparatus of claim 1, wherein the apparatus further comprises one or more process chambers, the one or more process chambers operative to perform at least one of substrate cleaning, substrate outgassing, substrate annealing, substrate drying, and substrate surface activation.

36. The apparatus of claim 1, wherein at least a portion of the apparatus is covered by a removable tape.

37. A method for depositing one or more materials on a substrate, the method comprising the steps of:
placing at least a portion of the substrate proximate to a plurality of deposition modules such that the substrate and each of the plurality of deposition modules define a respective one of a plurality of process spaces therebetween, each of the plurality of process spaces in fluidic communication with one or more of a plurality of draw gas injection chambers; and
separately injecting a first precursor gas and a second precursor gas into the plurality of process spaces while injecting a draw gas into the plurality of draw gas injection chambers, and injecting a sweep gas into the plurality of process spaces while injecting substantially no draw gas into the plurality of draw gas injection chambers.

38. The method of claim 37, wherein the deposition is by atomic layer deposition.

39. The method of claim 37, wherein the sweep gas and the draw gas have substantially the same composition.

40. The method of claim 37, wherein the residence time of the first precursor gas and the second precursor gas in each of the plurality of process spaces is less than or equal to about ten milliseconds.

41. The method of claim 37, wherein the first precursor gas is injected into the plurality of process spaces for a precursor injection time equal to about the residence time of the first precursor gas in the plurality of process spaces.

42. The method of claim 37, wherein the second precursor gas is injected into the plurality of process spaces for a precursor injection time equal to about the residence time of the second precursor gas in the plurality of process spaces.

43. The method of claim 37, wherein the residence time of the sweep gas in the plurality of process spaces is less than or equal to about ten milliseconds.

44. The method of claim 37, wherein the sweep gas is injected for a sweep gas injection time equal to about four to about five times the residence time of the sweep gas in the plurality of process spaces.

45. The method of claim 37, wherein injecting the sweep gas into the plurality of process spaces removes greater than 99% of any of the first and second precursor gases from the plurality of process spaces.

46. The method of claim 37, wherein the substrate is held stationary with respect to the plurality of deposition modules while depositing the one or more materials on the substrate.

47. The method of claim 37, wherein the substrate is continuously translated past the plurality of deposition modules while depositing the one or more materials on the substrate.

48. The method of claim 47, wherein two or more different coatings are deposited on the substrate while continuously translating the substrate past the plurality of deposition modules.

49. A product of manufacture formed at least in part by a method comprising the steps of:
placing at least a portion of the substrate proximate to a plurality of deposition modules such that the substrate and each of the plurality of deposition modules define a respective one of a plurality of process spaces therebetween, each of the plurality of process spaces in fluidic communication with one or more of a plurality of draw gas injection chambers; and
separately injecting a first precursor gas and a second precursor gas into the plurality of process spaces while injecting a draw gas into the plurality of draw gas injection chambers, and injecting a sweep gas into the plurality of process spaces while injecting substantially no draw gas into the plurality of draw gas injection chambers.
